(19) United States
(12) Patent Application Publication
(10) Pub. No.: US 2007/0215049 A1
(43) Pub. Date: Sep. 20, 2007

(54) Transfer of wafers with edge grip

(75) Inventors: Wolfgang Aderhold, Cupertino, CA (US); Teresa Trowbridge, Los Altos, CA (US)

Correspondence Address: Attn: Applied Materials;Law Offices of Charles Guenzer, 2211 Park Boulevard, P.O. Box 60729, Palo Alto, CA, 94306, US

(73) Assignee: Applied Materials, Inc.

(21) Appl. No.: 11/375,709

(22) Filed: Mar. 14, 2006

(51) Int. Cl. B32B 3/02; C23C 16/00

(52) U.S. Cl. 118/728; 428/64.1

(57) ABSTRACT

Three wafer support fixtures transfer a wafer for thermal processing in an inverted orientation within a heating chamber. Two co-planar support fixtures grab the wafer edge inside the chamber from a blade within a 1.5 mm wafer exclusion zone and hold it above the edge ring during heat-up and then withdraw thermal processing. A third support fixture chucks the wafer backside and transfers it to sloping support areas of the edge ring. The three support fixtures inside the chamber are individually controlled from outside. Alternatively, an arm connected to a controller is connected to the three support fixtures

### FIELD OF THE INVENTION

This invention relates generally to heat treatment of semiconductor wafers and other substrates. In particular, the invention relates to a method and apparatus for transferring a wafer within a heating chamber in a rapid thermal processing system as well as other wafer processing systems.

### BACKGROUND ART

The fabrication of integrated circuits from silicon or other wafers or different types of substrates such as glass flat panel displays or solar cells involves many steps of depositing layers and photo lithographically patterning the layers. Ion implantation may be used to dope active regions in the semiconductive silicon. The fabrication sequence also includes thermal annealing of the wafers or other substrates for many uses including curing implant damage and activating the dopants, crystallization, thermal oxidation and nitridation, silicidation, chemical vapor deposition, vapor phase doping, thermal cleaning, and other processesreasons. Although annealing in early stages of silicon technology typically involved heating multiple wafers for long periods in an annealing oven, rapid thermal processing (RTP) has been increasingly used to satisfy the ever more stringent requirements for ever smaller circuit features. RTP is typically performed in a single-wafer chamber by irradiating a wafer with light from an array of high-intensity lamps directed at the front face of the wafer on which the integrated circuits are being formed. The radiation is at least partially absorbed by the wafer and quickly heats it to a desired high temperature, for example above 600° C. or in some applications above 1000° C. The radiant heating can be quickly turned on and off to controllably heat the wafer over a relatively short period, for example, of a minute or less or even a few seconds. A typical thermal processing system of a Radiance RTP reactor, available from Applied Materials, Inc. of Santa Clara, Calif. is described in Peuse et al. in U.S. Pat. Nos. 5,848,842 and 6,179,466, all incorporated herein by reference in their entireties.

It is important during thermal processing to control the temperature of the wafer to a closely defined temperature, uniform across the wafer. Various means have been used to improve the uniformity of heat distribution across the wafer. Most recently, a method of enhancing the uniformity of rapid thermal processing (RTP) of patterned wafers has been developed and described by Aderhold et al. (hereafter Aderhold, Aderhold being the present inventor) in the U.S. patent application Ser. No. 10/788,979, filed Feb. 27, 2004 and incorporated herein by reference in its entirety. While Aderhold's design makes use of a somewhat typical thermal processing system of a RTP reactor, he discloses a new method of a backside wafer rapid thermal processing where the unpatterned back side of the wafer is positioned to upwardly face the radiant heat source, as opposed to the conventional positioning of the wafer with its patterned front side exposed to radiation, as disclosed in the U.S. Pat. No. 5,848,842 and 6,179,466.

FIG. 1 schematically represents a Radiance RTP chamber 10 described by Aderhold which may be vacuum pumped or be filled with a controlled gas ambient. A wafer 12 to be thermally processed is supported on its periphery by an edge ring 14 having an annular sloping shelf 18 contacting the corner of the wafer 12. The size of wafers is currently transitioning from 200 mm to 300 mm in diameter. Balance et al. more completely describe the edge ring 14 for a 300 mm wafer and its support function in U.S. Pat. No. 6,395,363, incorporated herein by reference in its entirety. In the backside reactor 10, the unpatterned back side 12a of the wafer 12 is positioned to face a radiant heating apparatus 20 while the patterned front side 12b faces a reflector 24 and is dynamically monitored for the temperature of the wafer 12. The wafer 12 is oriented such that processed features 26 already formed in a front surface 12a face downwardly, referenced to the downward gravitational field, while the generally unpatterned back side 12b that does not have features 26 formed therein is oriented toward a thermal processing area 28 defined on its upper side by a transparent quartz window 30. Features 26 constitute developing integrated circuit patterning within and near the plane of the surface of the wafer 12. It is understood that the processed features may be formed in an apparently planar and uniform surfaces. The radiant heating apparatus 20 is positioned above the window 30 to direct radiant energy toward the wafer 12 and thus to heat it. In the RTP reactor 10, the radiant heating apparatus 20 includes a large number of high-intensity tungsten-halogen lamps 32 positioned in respective hexagonal reflective tubes 34 arranged in a close-packed array above the window 30. However, other radiant heating apparatus may be substituted such as a scanned line/of laser radiation.

The reflector 24 forms a black-body cavity 36 below the wafer back side 12a that tends to distribute heat from warmer portions of the wafer 12 to cooler portions. A rotatable cylinder 38 supports the edge ring 14, and a supporting stator 40 is magnetically coupled to a rotatable rotor 41 positioned outside chamber walls 42. Three lift pins 43 may be raised and lowered to support the wafer 12 when the wafer is handed between a loading blade (not shown) that brings the wafer 12 into the chamber and the edge ring 14, on which the wafer 12 is thermally processed. The system is controlled by a computerized controller circuitry 44 which, among other functions, varies the voltage delivered to the lamps 32 in the different heating zones to thereby tailor the radial distribution of radiant energy to various areas of the wafer 12 based on the outputs of the pyrometers 46 which measure the temperature across the wafer.

FIGS. 2 and 3 are side and plan views of the wafer 12 oriented with its features 26 facing downwardly toward the reflector plate 24 and supported by a generally annular and sloping shelf 18 of the edge ring 14. The inverted wafer 12 has a beveled comer 12c which contacts the sloping shelf 18. The width of the edge ring shelf 18 is generally shortened over the shelf of a conventional reactor, so that the edge ring shelf 18 only minimally shields the front side 12b of the wafer 12 from the reflector 24.

Referring to FIG. 4, an edge exclusion zone 50 is an area on the wafer surface that is dominated by edge effects during wafer thermal processing such that any die 52 located within the edge exclusion zone 50 is highly likely to be defective or at least non-uniform relative to dies 52 located closer to the wafer center. Additionally, as a result of the arrangement of the rectangular dies 52 on a circular wafer 12, relatively large structured dye regions 56 develop at several locations near the periphery of the wafer 12 where no pattern is developed and these unpatterned areas thereby significantly affect the thermal uniformity. The exclusion zone 50 typically has a width of about 2 mm. For the inverted wafer geometry, the exclusion zone 50 is an area within a typical 300 mm wafer that in the invention is reserved for a wafer carrier to support the wafer. Dies may be formed within the exclusion zone, but they usually have less than the full rectangular area and in any case are not expected to be operative. Because a large part of the wafer front surface 12b is otherwise usable, it is imperative to avoid further damaging dies 52 by the wafer support features; otherwise, the quality of dies 52 may render any affected dies 52 inoperable.

Although the back-side RTP reactor 10 of FIG. 1 differs from the front-side processing reactor in only few ways, it offers improved efficiency. However, using an inverted wafer orientation in the RTP reactor for the most part designed for conventional upwardly facing orientation presents some difficulties with wafer support and handling.

One of the difficulties is that, as mentioned above, the wafer 12 should be supported on its front side 12b at its periphery only within its edge exclusion zone 50. While the lift pins 43 in a conventional RTP reactor typically contact the back side of the wafer 12 at positions underlying production dies 52, such contact in the backside reactor 10 will most likely introduce sufficient damage to the contacted dies 52 to render the dies inoperable. Further, to minimize yield loss for such RTP processing on multiple levels, it becomes important to rigidly maintain the orientation of the wafer patterning relative to the lift pins 43. One solution to this problem moves the lift pins 43 to areas of the structured dye regions 56, which, as discussed above, do not yield useful dies. However, this solution has disadvantages. First, it requires careful orientation of the wafer patterning relative to the location of the lift pins 43. Secondly, different integrated circuit designs likely have different die sizes and ratio of length to width. As a result, the location and size of the structured dye regions 56 may vary from one IC design to another. Accordingly, it may be necessary to move the locations of the lift pins 43 when processing a different IC design. Although feasible, this design is economically disadvantageous.

Another solution moves the lift pins 43 to the edge exclusion zone 50 of the wafer 12, preferably within the same peripheral wafer region overlapping the edge ring shelf 18. As a result, however, the edge ring 14 requires redesign around the areas of the lift pins 43. As shown in FIG. 3, a cut-out 62 is formed in the inner periphery of the shelf 18 to accommodate the lift pins 43 positioned to correspond to the wafer edge exclusion zone 50 and to allow the lift pin 32 to pass the edge ring 14 and support the wafer 12 above the edge ring shelf 18. Such a structure is replicated for all the lift pins 43. A problem with this solution is that the support may not be sufficiently reliable to avoid light leakage around the edge ring 14 as it provides only minimal overlap to the wafer 12 in the areas of the cut-outs 62.

Peuse et al. in U.S. Pat. No. 6,179,466 disclose another support configuration in which the backside of the wafer contacts a substantial radial extent of the edge ring shelf. It may be possible to modify this support arrangement such the actual extended contact bf the edge ring 14 to the wafer 12 may be within the wafer edge exclusion zone 50. However, again, for supporting the wafer in an inverted orientation, a redesign of the edge ring 14 and closer tolerances would be necessary to accommodate a lifting mechanism, such as lift pins 43. The new design would present complications as it would have to meet the requirements of the thermal process, i.e., the combined structure of the lifting pins 43 and the edge ring 14 must be capable of minimizing the leakage of the high-temperature radiant energy from the radiant heat source 20 around the edge ring 14 on either its inner or outer side. This means that the wafer 12 must be light sealed to the edge ring 14. The edge ring 14 can overlap the dies 52 inside the edge; however, it must be within the exclusion zone 50 and no contact should be is made to the dies 52. Additionally, the edge ring 14 must have a construction that does not degrade the temperature uniformity across the wafer 12. However, even if all these requirements were met, this arrangement presents still another problem because the pins 43 would support the wafer so close to the wafer edge that the wafer will be unstable. A less stable support structure requires that the wafers be moved more slowly, so that they do not slide off the lift pins 43. Thus, the throughput of the processing system is decreased. Still another problem is that, since the 300 mm wafers are so large, a wafer may bow, or sag, in the middle, between the supporting pins. Finally, for this arrangement, the inverted orientation of the wafer would require a more sophisticated, and therefore more expensive, loading blade assembly to move the wafer into and out of the RTP reactor. Substantial redesigning of the edge ring and loading blade to cooperate with the lift pins 43 is undesirable due to the expense and time that would be required.

Thus, a handling mechanism is needed for a wafer in an inverted orientation as well as for other applications that cooperates with existing thermal process tools, may be used in any heating chamber, avoids the exclusion zones, provides a stable support for the wafer, and may be included in an existing thermal process of the inverted RTP reactor without degrading its characteristics.

### SUMMARY OF THE INVENTION

One embodiment of the present invention includes an apparatus for transferring a wafer during thermal processing. The wafer handling apparatus comprises a loading blade for delivering the wafer into the heating chamber and at least three wafer handlers for transferring the wafer between the loading blade and an edge ring in an inverted orientation. At least two wafer handlers are edge handlers for supporting the wafer at two opposite wafer edges thereof within a distance that is less than the wafer edge exclusion zone, and one of the two edge handlers is configured to restrain the wafer from lateral movement, while another edge handler is configured to adapt to the thermal expansion of the wafer. The third handler is configured to gravitationally support the wafer in a horizontal position independently from the co-planar edge handlers. The three handlers transfer the wafer without movement of the loading blade.

Another embodiment of the present invention includes a wafer lifting apparatus. The apparatus comprises a drive and an arm connected to the drive. Three effectors are coupled to the arm and adapted to gravitationally support a wafer in an invert orientation during transfer. Two effectors are co-planar with the front surface of the wafer and support the wafer in a horizontal position at two opposite edges within a distance that is less than the wafer exclusion zone, preferably, less than 1.5 mm. In one embodiment, one of the two edge or end effectors is configured to restrain the wafer from lateral movement, and another is configured to compensate for the thermal horizontal expansion of the wafer. The third effector supports the wafer from a back side independently from the two end effectors by chucking the wafer for example, with a vacuum. The back effector and the arm comprise a vacuum passage connected to the vacuum source.

The three effectors may be manipulated within the heating chamber through vacuum tight sealed apertures, with the arm positioned outside of the heating chamber. The sealed aperture may include a two-dimensionally flexible bellows. Alternatively, the arm may be manipulated the within the heating chamber through a vacuum tight sealed aperture. The sealed aperture can be configured to flexibly compensate for the movement of the end effectors and the back effector, or, alternatively, of the arm. A controller may be connected to the drive and the vacuum source to independently control the end effectors, the back effector and the arm. The three effectors and the arm may be made out of quartz.

A method of the present invention may include loading and unloading a wafer into and out of a heating chamber for thermal processing in which a wafer is delivered on a loading blade with a front side facing downwardly. Two effectors are moved to support the wafer in a horizontal inverted orientation at opposite edges within less than 1.5 mm contact, to restrain it from lateral movement, and to compensate for the thermal expansion of the wafer. The loading blade is retracted, and the effectors are lowered to the position of pre-heat. After the pre-heat, the wafer is loaded on an edge ring for thermal processing, and the end effectors are retracted. A back effecter then is lowered to grip the wafer at a back side, by chucking, and to unload it from the edge ring. Next, the back effector is moved to position the wafer for being placed over the two end effectors that are moved to receive and support the wafer. The back effector is retracted, and the loading blade is extended to receive the wafer and remove it from the chamber as the loading blade is retracted.

### BRIEF DESCRIPTION OF THE DRAWINGS

FIG. 1 is schematic cross-sectional view of an RTP reactor in which the invention may be practiced.

FIG. 2 is sectional view of an inverted wafer supported by an edge ring.

FIG. 3 is plan view of a portion of the edge ring modified to accommodate lift pins positioned at the edge of the wafer.

FIG. 4 is plan view of the dies arranged on a wafer.

FIG. 5 is plan view of the invention showing a wafer supported by three waferhandlers during wafer transfer in an inverted orientation within an RTP reactor.

FIGS. 7 and 8 are respective plan and cross-sectional views of a loading blade holding a wafer in an inverted orientation.

FIG. 9 is plan view of an edge handler.

FIG. 10 is schematic cross-sectional views of a restraining edge handler.

FIG. 11 is schematic cross-sectional view of a compensating edge handler supporting a wafer in an inverted orientation.

FIGS. 12 and 13 are detailed sectional and plan views of a shelf for wafer edge support.

FIG. 14 and 15 are side and plan views of a compensating and restraining edge handlers penetrating the heating chamber with bellows for sealing an aperture in the chamber wall.

FIGS. 16 and 17 are side views of bellows in fine positioning mode for wafer lifting position and wafer lowering position.

FIG. 18 is side view of a back handler supporting a wafer from a back surface.

FIG. 19 is detailed view of a back handler with bellows for sealing an aperture in the RTP reactor.

FIG. 20 is a bottom plan view of a pneumatic cup.

FIGS. 21 is a schematic cross-sectional view of a back handler supporting a wafer by vacuum chucking.

FIGS. 22A-22G are schematic cross-sectional views of a wafer loading process.

FIGS. 23A-23F are schematic cross-sectional views of a wafer unloading process.

### DETAILED DESCRIPTION OF THE PREFERRED EMBODIMENTS

FIG. 5 shows a plan view of a wafer transfer apparatus 100 incorporating features of the present invention. Although the present invention will be described with reference to the embodiments shown in the drawings, it should be understood that this invention may be embodied in many alternate forms of embodiments. In addition, any suitable size, shape or type of elements or materials could be used. The wafer transfer apparatus 100 is adapted to transport wafers such as semiconductor wafers, such as silicon, gallium arsenide, semiconductor packaging wafers, such as high density interconnects, semiconductor manufacturing process imaging plates, such as masks or reticles, and large area, possibly rectangular, display panels, such as active matrix LCD panel, field emission arrays, plasma displays, other display panels or other applications such as solar cells.

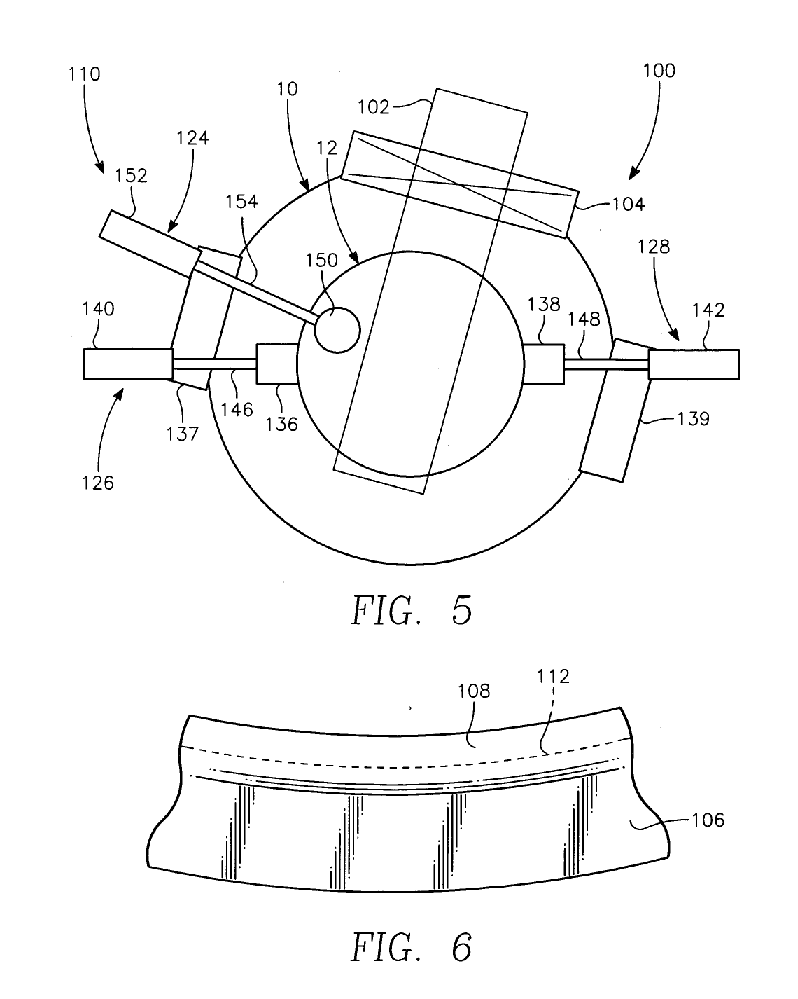

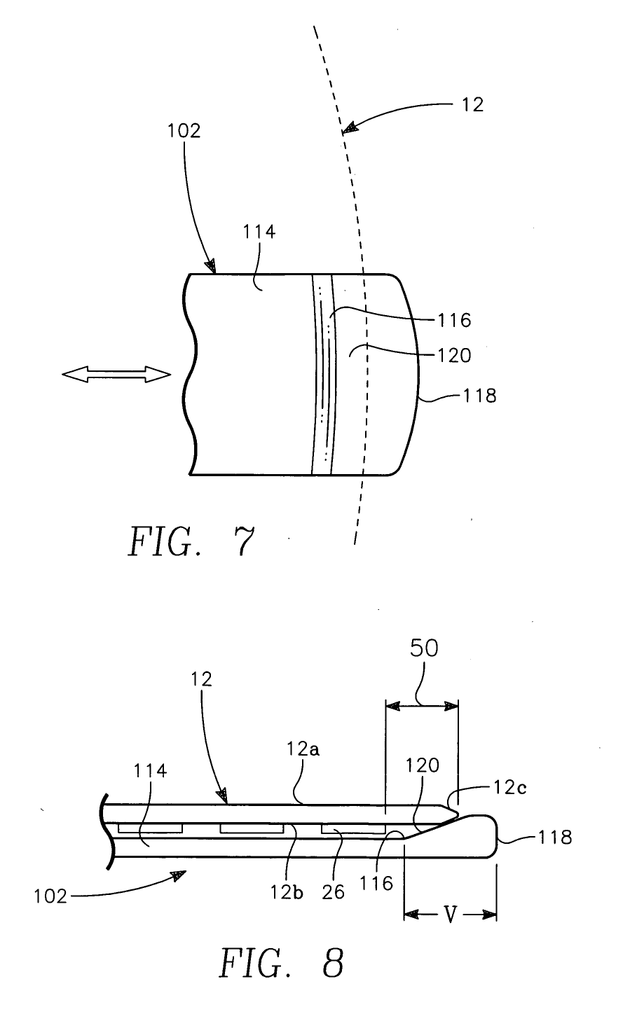

As shown in FIG. 5, the wafer transfer apparatus 100 includes a wafer blade 102 configured to transfer the wafer 12 into and out of the rapid thermal processing (RTP) chamber 10 through a vacuum sealable slit valve 104 and to hold the wafer 12 with the wafer front side facing downwardly. The wafer transfer mechanism 100 additionally includes a wafer lift mechanism 110 for transferring the wafer 12 in inverted orientation between the wafer blade 102 and an edge ring 106, illustrated in the partial plan view of FIG. 6. Similarly to the wafer blade 102 illustrated in the plan and cross-sectional views of FIGS. 7 and 8, the edge ring 106 of FIG. 6 has an inwardly and downwardly extending and sloping shelf 108 to engage and support the wafer 12 within is edge exclusion zone 50, for example, at a contact or shielding line 112.

FIGS. 7 and 8 illustrate respective plan and cross-sectional views of a modified wafer blade 102 of FIGS. 7 and 8 designed for use with the inverted wafer 12. Conventional wafer blades for upwardly oriented substrates support the wafer on significant portions of the wafer's gravitational bottom. Such support, however, would likely incur severe damage to the downwardly facing wafer 12 because its supported side contains the developing IC structure. The modified wafer blade 102, disclosed in the aforementioned U.S. patent application Ser. No. 10/788,979, includes a substantially flat inner portion 114 having on each of its two axial ends a transition 116 to a support end 118, having a sloping shelf 120 which slopes upwardly in the outward direction in a support section while being circularly symmetric about the wafer center to the lateral extent of the blade 102. The sloping shelf 120 supports the beveled corner 12c of the wafer 12 and the central part of the wafer 12 elevated above the inner blade portion 114. A similar end configuration occurs at the opposite unillustrated end of the wafer blade 102. The principal motion of the wafer blade 102 is along its axis to transfer the wafer 12 to and from the heating chamber 10 from the transfer chamber. The wafer blade 102 is typically mounted on a frog-leg robotic operator, well known in the field, so that it can move back and forth in and out of the heating chamber 10 from the central transfer chamber as well as rotate within the transfer chamber. One or more wafer blades 102 may be used for transferring the wafers between the heating chamber and the outside environment. When the wafer blade 102 brings the wafer 12 to the heating chamber 10, the lift mechanism 110 of FIG. 5 moving from the lateral sides of the blade 102 lifts the wafer off the wafer blade 102, after which the wafer blade 102 withdraws.

The wafer lift mechanism 110 of FIG. 5 may have multiple wafer handlers for lifting and handling the inverted wafer in a heating chamber of the reactor 10. In a preferred embodiment, the lift mechanism 110 has three wafer handlers 124, 126, 128. Two of the three wafer handlers are edge handlers 126, 128, positioned to engage generally opposed edges of the wafer 12 to be lifted or lowered. The third wafer handler is a back handler 124 positioned, when activated, to support the wafer 12 on its featureless backside against the force of gravity. The edge handlers 126, 128 have respective positioning end effectors 136, 138, respective actuators 140, 142 and respective arms 146, 148 connecting effectors 136, 138 with the actuators 140, 142 located at the ends of the arms 146, 148 usually outside the chamber. The back handler 14 includes a pneumatic cup 150 connected to an actuator 152 connected by an arm 154.

The temperature in the RTP reactor tends to rapidly rise. Desired high temperatures for thermal processing in RTP can range from above 600° C. to above 1200° C. in some applications and by reaching the elevated temperatures from room temperature within a few seconds. Therefore, the edge ring 106 made out of a silicon-containing material reaches high temperatures very quickly and which does not completely cool between thermal processing cycles. If the wafer 12 is brought into the chamber 10 from an outside environment and placed immediately on the heated edge ring 106, the high temperature differential can significantly damage the processed wafer features 26 and possibly fracture the water 12. Consequently, the wafer 12 should be pre-heated prior to being placed on the edge ring 106. The edge handlers 126, 128 are used to transfer the wafer 12 to a pre-heat position, to support the wafer during the pre-heat, and then to transfer the wafer 12 to a processing position on the edge ring 106. It is important to ensure that during the transfer, the handlers 124, 126, and 128 have sufficient structural integrity to support the wafer 12 and that they do not interfere with the movement of the loading blade 102.

As discussed above, the high temperatures used in the wafer thermal processing can compromise the structural integrity of the wafer support system. Therefore, the wafer handlers 124, 126, 128 or at least the effectors 136, 138, pneumatic cup 150, and arms, 146, 148, 154 should be made of materials capable of maintaining sufficient integrity under these conditions. Typically, in the normal thermal processing, materials such as steel, aluminum, molybdenum, other appropriate metal, or even some plastics are successfully used for the wafer handlers. However, in the RTP reactors where a wafer surface is scanned with a line of radiation having a power density about 200 kW/cm², the wafer handler can be heated to approximately 650° C., with ramp-up and ramp-down rates exceeding 200° C./s. The wafer handlers of conventional design and materials are often not able to perform in these conditions with the required degree of reliability. When used for the above-described thermal processing, these materials sometimes react with the wafer surface or shed particles onto the wafer, thus creating particulate contamination decreasing wafer yield.

Therefore, the wafer handlers 124, 126, 128, of the invention are preferably formed from a highly heat resistant rigid material, chemically inert, and resistant to cracking, chipping, flaking or other particle generation. Rigidity is necessary to ensure that the wafer handler is straight, flat and does not bend in the conditions of RTP heating chamber. As will be discussed in more detail below, this is especially important for the edge handlers 126, 128 due to the requirement for their precise co-planar horizontal positioning for transferring the wafer in inverted orientation and holding the water during pre-heating. To ensure structural and chemical integrity and straightness, the wafer handlers 124, 126 may be constructed of quartz or other a rigid material that will not readily bend even at high temperatures and is also highly heat and chemically resistant. Examples of other suitable materials include ceramic or ceramic-based compounds, such as alumina, closely related to Al₂O₃.

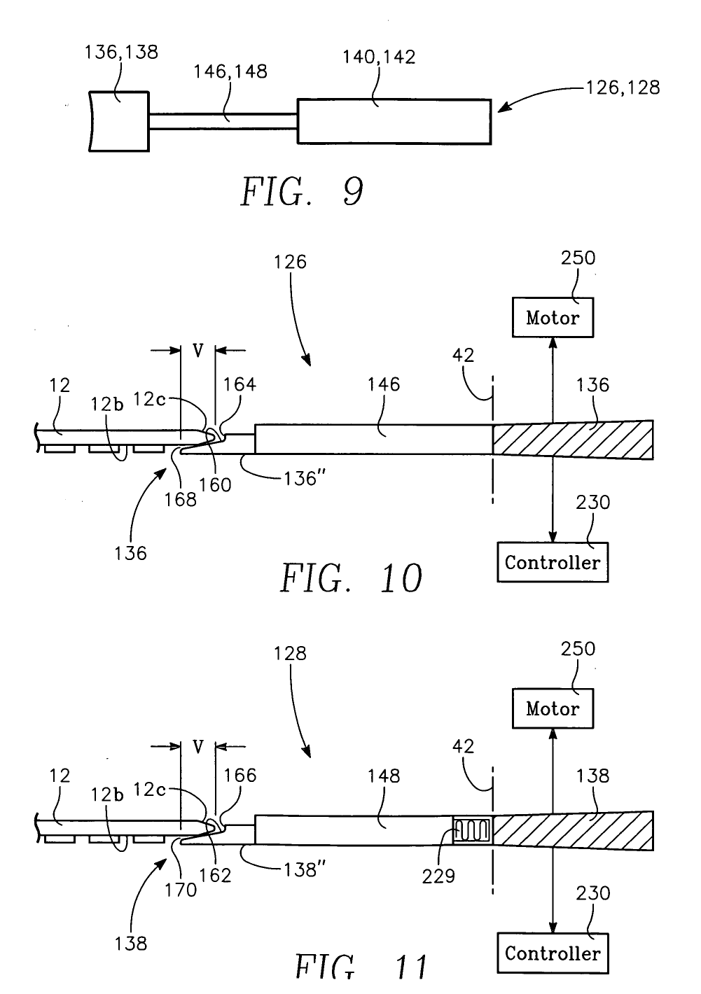

FIGS. 9, 10, and 11 show top and side views of the edge handlers 126, 128. To ensure that the wafer 12 is properly positioned while supported by the edge handlers 126, 128, and end effectors 136, 138 have sloping support surfaces 160, 162 , respectively, which contact the wafer 12. For a greater stability of the wafer 12 during transfer, the effectors 136, 138 should be positioned so that the wafer 12 is supported in a horizontal plane perpendicular to the direction of the wafer transfer and centered between the edge handlers 126, 128 and their effectors 136, 134. To accomplish this, the medians of the end effectors 136, 138 are configured to be co-planar with respect to each other and with respect to the front surface 12b of the inverted wafer 12, that is, having their bottom surfaces 136″, 138″, respectively, positioned below the plane of the front side 12b of the wafer 12 where the shelves effectors 136, 138 contact the wafer 12.

The edge handlers 126, 128 must also be able to remove the wafer 12 from the loading blade 102 without crossing each other's paths in the heating chamber 10 and without blocking the movement of the wafer blade 102 of FIG. 5 out of the heating chamber. Additionally, the standard positions for the end effectors 136, 138 must be defined such that all edge handlers can interface properly with all loading blades regardless of the number of the edge handlers and loading blades. This is accomplished by positioning the end effectors 136, 138 at diametrically opposite sides of the wafer 12 at locations on either lateral side of the loading blade 102, thus not interfering with the wafer blade 102.

It should be appreciated that while the edge handlers 126, 128 are depicted as single-effector structures each having attachments for only one positioning effector 136, 138, respectively, and each supporting only one wafer 12 at a time, a multi-shelf configuration (not shown) is also available, where each wafer handler has an attachment for two or more end effectors 136, 138 and can support two or more wafers 12 at a time. Also, more then two co-planar edge handlers may be attached to the actuator 140, 142 as long as they do not interfere with retraction of the loading blade 102.

As discussed above, another problem associated with most of the existing wafer handling designs is that die yield at the edges of the wafers is reduced because the active surface area of each wafer is diminished by the intrusion of the end handlers. When thin wafers having devices on a front side are transferred with the devices on the front side of the wafer facing down toward the support areas of the end effectors 136, 138, the appropriate configuration of the end effector 136, 138 to support the wafer 12 in an inverted positions becomes very important. The farther the end effectors 136, 138 intrude into the front surface 12b of the wafer 12 front surface, the larger the area on the surface of the wafer 12 that is rendered commercially useless.

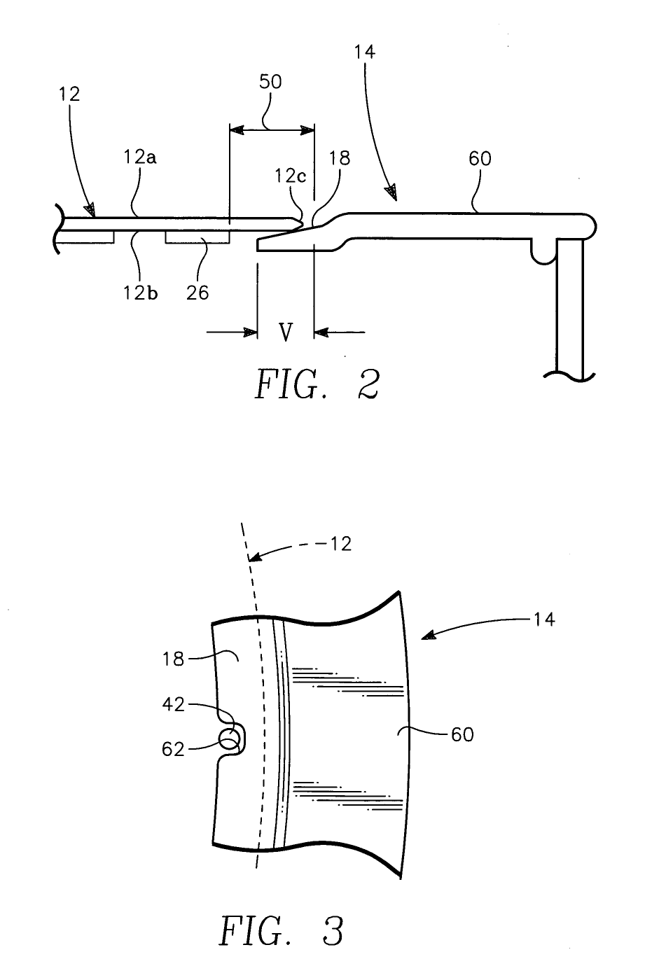

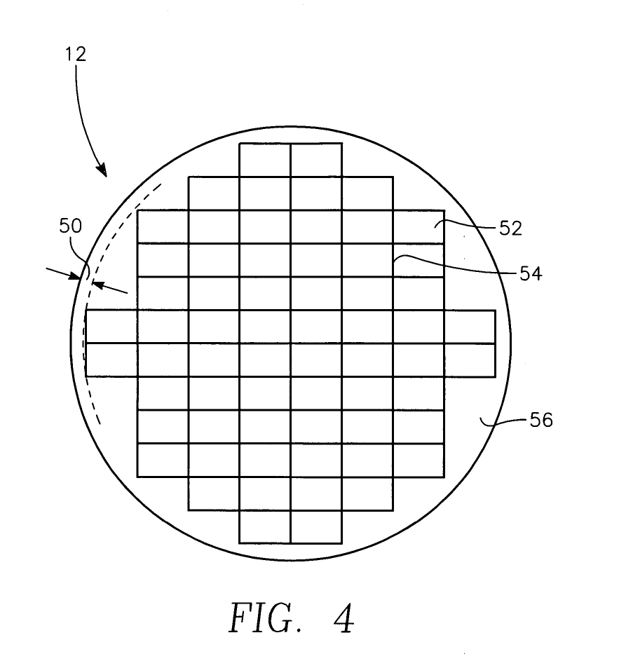

For each wafer size, Semiconductor Equipment and Materials International (SEMI) created the SEMI Wafer Carrier and Interface Standard to define an industry standard configuration for an appropriate wafer carrier. The SEMI Wafer Carrier and Interface Standard defines areas, described above as exclusion zones 50, in any portion of which the edge end effector 136, 138 may be disposed. For example, the edge exclusion zones 50 for 300 mm wafers, as shown in FIG. 2, typically have a width of about 2 mm. Although the edge handlers 126, 128 are designed to support 300 mm wafers, other edge handlers incorporating the present invention may be designed to support wafer of other size, such as 100 mm, 150 mm or 200 mm.

As shown in FIGS. 10 and 11, the end effectors 136, 138 are designed such that the distance Vat which the effectors 136, 138 contact and overlap the wafer front surface 126 on its periphery with their sloping contact surfaces 160, 162, respectively, does not exceed 2 mm. Preferably, the distance V is maintained within 1.5 mm, or less, i.e., the wafer 12 should be held by the effectors 136, 138 at the wafer edges with less than 1.5 mm contact or shadowing to the surface on the front side 12b of the wafer around the edges. To accomplish that, the sloping support surfaces 160, 162 terminate at their proximal end at respective walls 164, 166, forming pockets 168, 170 within the effectors 136, 138, respectively. The pockets 168, 170 laterally restrain the wafer 12 such that while the area of contact and overlap can't exceed the pre-selected 1.5 mm distance, the pockets 168, 170 limit the clearance for the wafer edges to the narrow spaces within the pockets 168, 170. The depth of the pockets 168, 170, which is determined by the height of the walls 164, 166 and the slope of the support surface 160, 162 can vary. Preferably, the depth of the pockets 168, 170 should not be less than the thickness of the wafer 12 to contain the entire edge of the wafer. Although the contact surfaces 160, 162 are illustrated as being sloped, they may be flat and contact the periphery of the wafer 12 over a substantial extent of its exclusion zone 50.

However, as discussed above, there is a concern with regard to a minimal area of the contact when transferring a wafer in an inverted orientation that the wafer may become unstable when supported in its a narrow peripheral exclusion zone.

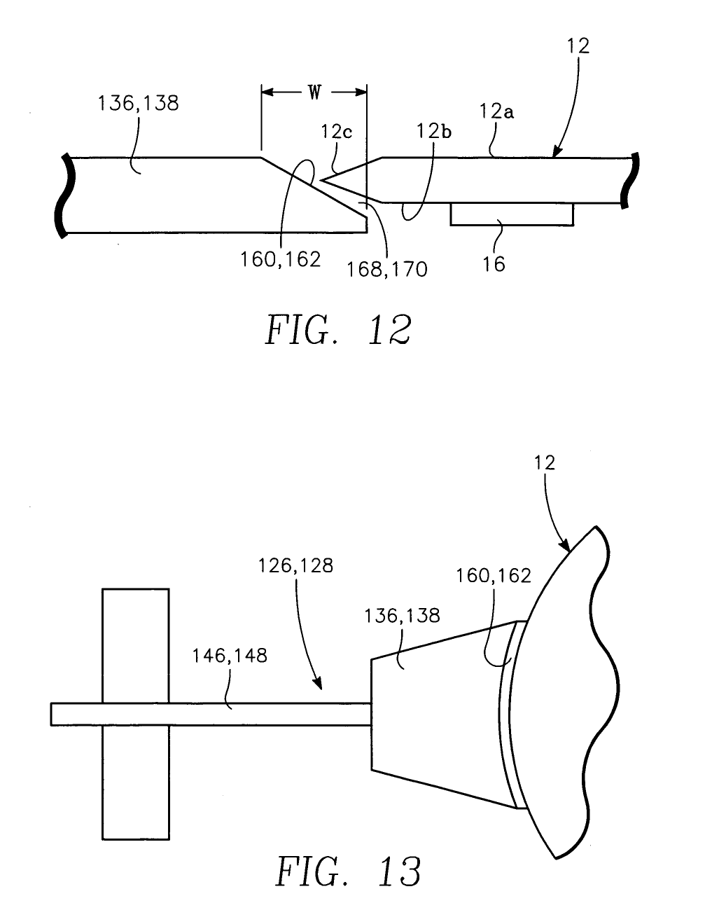

FIGS. 12 and 13 illustrate in detail a solution to this problem. The sloping support surfaces 160, 162 of the respective effectors 136, 138 have a sloped profile within the distance W equal or less than 1.5 mm. Forming the sloping support surfaces 160, 162 at an angle β inclined relative to the horizontal surface of the front side of wafer 12 allows a minimal contact area to be maintained between the wafer 12 and the effectors 136, 138 on both sides of the wafer 12 while providing for a greater stability of the wafer. For example, the angle β of approximately 45-48° would sufficiently accommodate the wafer edges and ensure the stability of its position on the effectors 136, 138. The slanted angle β creates radial cut-outs along the perimeter of the end of the effectors 136, 138 that are approximately 5% larger that the radii of the wafer. This innovative structure permits for the front surface 12b of the wafer 12 to contact the sloped surfaces 160, 162 only at a minimal contact line on the opposite sides of the wafer 12, such that the wafer edges are maintained on both sides within the exclusion zone of 1.5 mm. Thereby, the defects across the wafer front surface caused by handling are minimized. Additionally, the sloped profiles of the pockets 168, 170 permit for slight wafer realignment if the wafer is radially offset. Thus, the wafer 12 is provided with at least two fixed stable supports that firmly hold it on the edge handlers 126, 128 in a horizontal position for transfer within the heating chamber. At the same time, this design avoids damaging the delicate devices on the lower wafer front surface 12b by preventing them from coming in contact with the large portion of the shelf as is done in the existing wafer handlers. To ensure that the wafer 12 is present on the effectors 136, 138, one or both of the effectors 136, 138 may have a wafer sensor (not shown) at a standard location for permitting a sensor beam, such as an infrared beam, to detect the presence of the wafer 12.

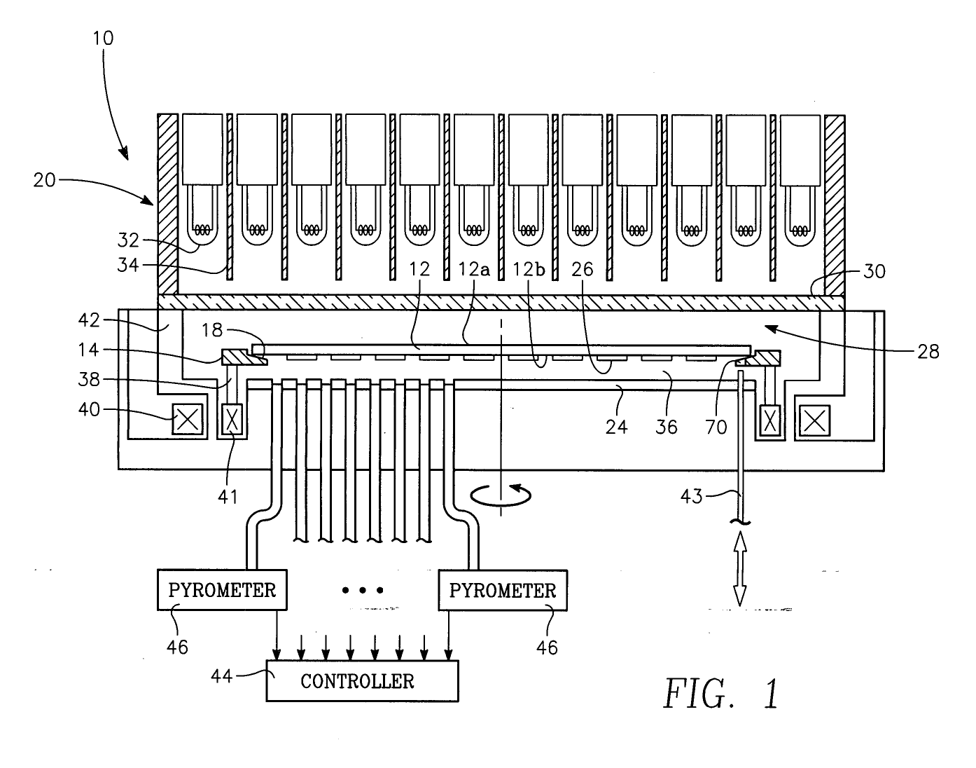

In operation, the end effectors 136, 138 hold the wafer 12 within the pockets 168, 170 during its transfer to the pre-heating position, and then hold the wafer for a time period required for pre-heating while the lamps 32 of FIG. 1 are turned on. When the pre-heat is completed, the end effectors 136, 138 lower to leave the wafer 12 supported on the edge ring 104. The support line of the end effectors 136, 138 of the edge handlers 116, 118 do not pass beyond the exclusion zone 50 when lifting or setting down the wafer 12, nor there is an interference with the loading blade 102's movement or positioning of the wafer on the edge ring 104. Most significantly, the design of this invention allows a wafer to be transferred in a heating chamber in a stable fixed position without vertical movement of the loading blade 102.

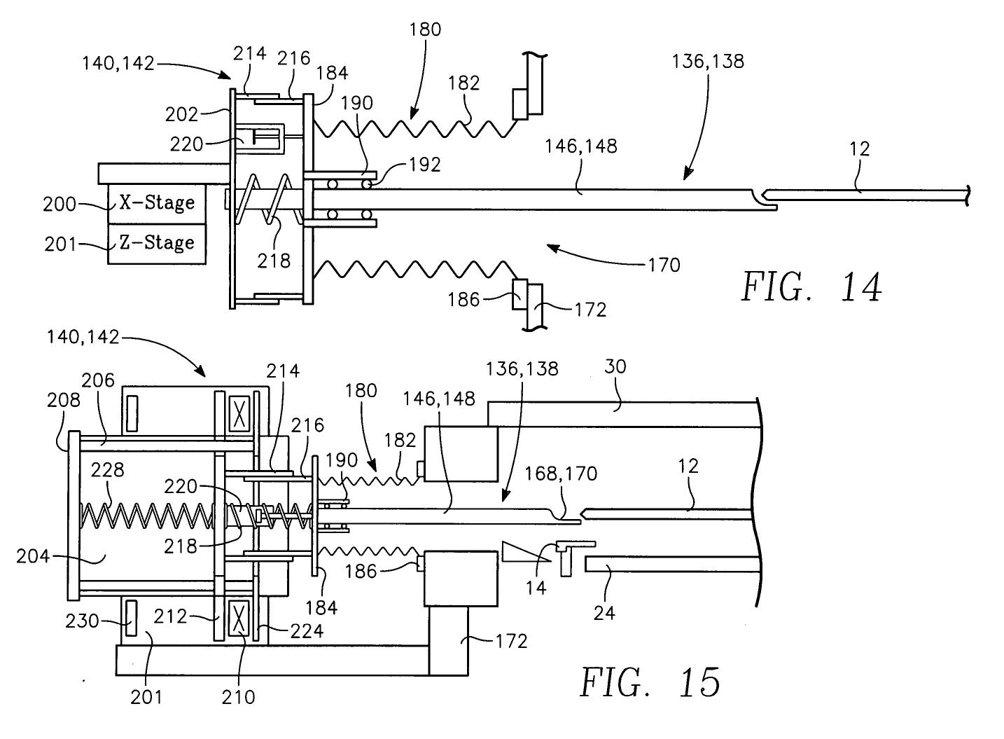

FIGS. 14 and 15 show side views of the compensating and restraining edge handlers 126, 128 operating within the RTP or other heating chamber 10. To accomplish this, the wafer handlers 126, 128 penetrate the walls of the RTP reactor through apertures in a chamber wall 172 forming the sealed heating chamber 10. The sealed apertures restrict contaminants, such as corrosive or abrasive liquids, from entering the heating chamber and maintain the temperatures and pressure of the thermal process. A bellows assembly 180 includes bellows 182 sealed on its outer by a metal bellows plate 184 and sealed on inner side to the wall 172 of the heating chamber through an annular static seal, such as a gasket, o-ring, or clamp. The bellows assembly 180 operates as a protective vacuum tight seal for the inside of the heating chamber at the points of penetration by the respective edge handlers 126, 128. Maintained under a static pressure, the bellows assembly 180 acts as a barrier and flexibly seals the aperture in the heating chamber 10. Alternatively, the bellows 180 can be maintained under a dynamic pressure that can be either supported by the pressure system of the heating chamber, or be supported by their own independent source. Commercially available parts may be used to perform function of the bellows 180 for the purposes of this invention.

As shown in FIGS. 14 and 15, the arm 146, 148 is held at its proximal end by a cantilever support 190 extending from the bellows end plate 184 and supporting and vacuum sealing the arms 146, 148 with O-rings 192. The embodiment of FIG. 15 provides two-directional movement of the actuator 140, 142 through a stacked arrangement of an X-stage 200 movable in the radial direction of the wafer 12 and a Z-stage 201 movable in the vertical direction perpendicular to the principal surface of the wafer 12. An actuator plate 202 extends along the vertical direction and fixed to an actuator housing 206 and back plate 208. The embodiment of FIG. 14 is somewhat schematic. The embodiment of FIG. 15 provides similar motion with the Z-stage 201 and an electromagnetic actuator 204 implementing the X-stage 200. The electromagnet actuator 204 includes an electromagnet 210 and a magnetic yoke 212, which moves along the actuator housing 206. In both embodiments, the base of the Z-stage 201 is supported in a fixed position relative to the wall 172 of the heater chamber 10 and the top of the Z-stage 201 supports the X-stage 200 or the electromagnetic actuator 204.

A telescope structure including two coaxial tubes 214, 216 supports the bellows end plate 184 on the actuator plate 202 or on the magnetic yoke 212. The two tightly fitting but slidable coaxial tubes 214, 216 are fixed respectively to the bellows end plate 1 and the actuator plate 202 or the magnetic yoke 212. A compression spring 218 is coupled between the bellows end plate and the actuator plate 202 or the magnetic yoke 212 to bias the inner tube 216 towards the center of the chamber 10 but to allow a horizontal force to radially deflect the tube 216 outwardly if necessary. Absent a horizontal force applied to the end effectors 136, 138, the bellows end plate 184 is separated from the actuator plate 202 or the magnetic yoke 212 by the uncompressed length of the compression spring 218. A pneumatic shock absorber 220, which includes a piston loosely sealed to and sliding in a cylinder, is coupled between the bellows end seal 184 and the actuator plate 202 or magnetic yoke 212 to damp the acceleration of the end effectors 136, 138 relative to the actuators 140, 142 to allow a fast separation of the end effector 126, 128 and the wafer 12.

The structure of the bellow assembly 180 enables the actuators 140, 142 to move respective arms 146, 148 laterally as well as vertically within the heating chamber 10 to load and unload the wafer 12 from the blade 102. To accomplish this purpose in the embodiment of FIG. 14, the X-Z stage 200 independently moves the actuator plate 202 and hence the end effector 136, 138 in the vertical and radial directions of the wafer 12. To accomplish this purpose in the embodiment of FIG. 15, the Z-stage 204 moves the back plate 208 and the actuator housing 206 which supports and slidably guides the magnetic yoke 212. The actuator 140, 142 of FIG. 15 comprises the electromagnet 210 fixed to a front plate 204 and the actuator housing 206 and hence slidably supporting the movable magnetic yoke 212, a tension spring 228 connected between the magnetic yoke 212 and the back plate 208, and a stop 230 fixed relative to the actuator housing 206. The electromagnet 210 effectuates the movement of the actuator 140, 142. When the electromagnet 210 is energized, it generates sufficient magnetic force to attract and hold the magnetic yoke 212 against the force of the tension spring 228 in a loaded position adjacent the electromagnet 210 as the tension spring 228 is expanded. When the electromagnet 210 is de-energized, the tension spring 228 returns the magnetic yoke 212 to its relaxed position against the stop 230. Contraction of the tension spring 228 allows the actuator 140, 142 to move in the horizontal direction, thus retracting the effector 136, 138 away from wafer 12 within the heater chamber 10. In the retracted position of both actuators 140, 142, the wafer 12 is released and the vulnerable effectors 136, 138 are in a safe operational position. When the electromagnet 210 is de-energized and the tension spring 228 is compressed, the magnetic yoke 212 retracts to release the wafer 12 to a safe position. Since the electromagnet 212 can be quickly de-energized, the retraction of the end effectors 136, 138 can be performed rapidly. Similarly, the end effectors 136, 138 can be quickly moved towards the center of the heat chamber 10 and assume a fine positioning mode adjacent the wafer 12 as soon as power is applied to the electromagnet.

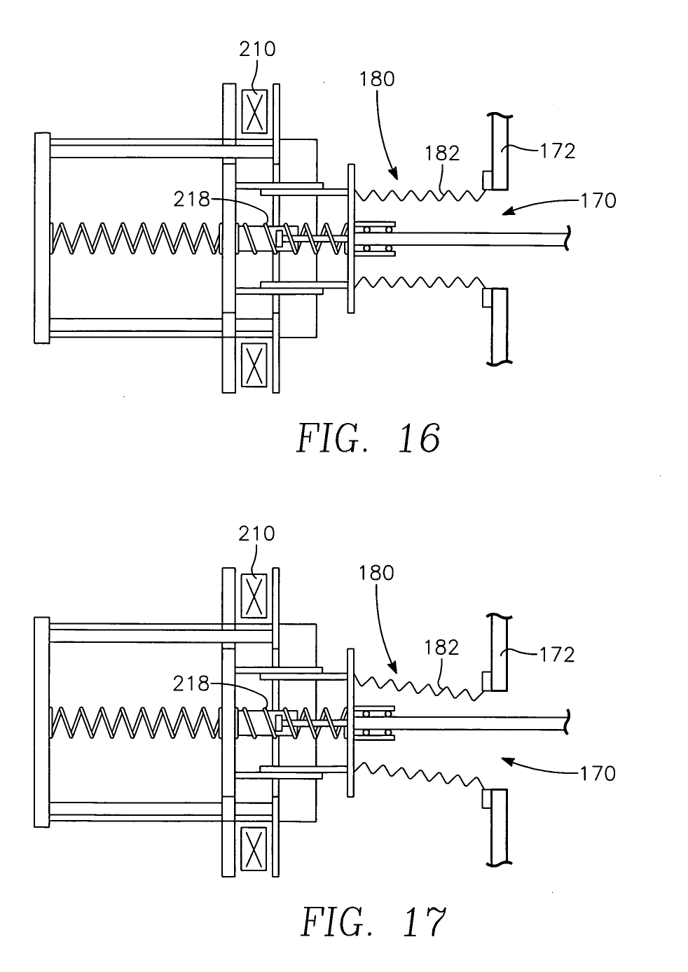

Once the end effector 136, 138 is located in the wafer portion of the heating chamber 10 in the fine positioning mode, the X-Z stage 200 or Z-stage 204 is enabled to vertically to lower and raise the wafer 12 during its transfer within the chamber to and from the wafer blade 102 and to and from the pre-heat position as well as to move apart to clear the way for the blade 102 out of the heating chamber. FIG. 16 illustrates the operation of the bellows assemblies 180 in a wafer lift position, while FIG. 17 shows the bellow assembly 180 in a position with the bellows 182 inclined with respect to the horizontal. Although the electromagnet actuator is illustrated, the X-Z actuator may also be used for the horizontal motion. To accomplish this, the bellows 182 must be structurally configured such that it has mechanical flexibility sufficient to enable all necessary manipulative motions of the wafer handlers 114, 116, 118 from outside of the chamber in the two directions required for transferring the wafer 12. Specifically, the bellows 182 must be made of materials allowing for elasticity and compression suitable for the bellow assemblies' operations while remaining vacuum tight. Additionally, the materials for the bellow assemblies must have sufficient heat resistance and chemical inertness to withstand the conditions of the RTP heating chamber. For example, the material for the bellows maybe stainless steel or other strong and oxidation resistant materials. Such bellows are commercially available.

In operation, the arms 146, 148, inserted inside the heating chamber via the bellows 182, move the wafer 12 within it, while the actuators 140, 142 move on the external side of the bellows 182. Thus, the actuators 140, 142, separated from the heating chamber by the bellows 182, control the operation of the wafer handlers 126, 128 from the outside of the chamber 10.

In another embodiment, the arms 146, 148 and end effectors 136, 138 are each connected to a step motor (not shown) or computerized micromanipulators (not shown) to effectuate the movement of the edge handlers 126, 128 from the outside of the heating chamber. Commercial micromanipulators can be used to individually control, exact position, move laterally and vertically, and fine tune each of the end effectors 136, 138. It should be understood that while the actuators 140, 142 are shown as positioned outside of the heating chamber, alternative configurations may be possible. For example, the actuators 140, 142 may be extended inside of the heating chamber through sealed apertures in the heating chamber and may be connected to an arm connected to a motor and computer, as will be discussed below.

As discussed above, another problem with handling inverted wafers in the heating chamber is that the wafers 12 tend to substantially expand during thermal treatment at high temperatures ranging from about 600° C. to about 1200° C. Expansion is also a concern when the 300 mm wafers 12 are pre-heated on the edge handlers 126, 128 because they expand against the walls 164, 166 or out of the pockets 168, 170.

The compression spring 218 of FIGS. 14 and 15 included within one edge handler 128 provides adaptive correction of the edge handler 128 for thermal expansion of the wafer 12 during heat-up. The compression spring 218 can be a spring positioned between the actuator plate 202 or the magnetic yoke 212 and the bellows end plate 184 and designed to change its shape and contract when subjected to a force from the wafer expansion during heating. Alternatively, the compression spring 218 can be substituted by a resilient insert 229 shown in FIG. 11 positioned between the end effector 138 and the arm 148. The arm 148 may be formed with a short recess in any portion along its length, in which the resilient insert 229 may be placed to compensate for the thermal expansion of the wafer 12. The insert 229 should have a constant width, equal to or less than the width of the arm 148 and may be made of a single resilient material, but of sufficient strength in the lateral dimension to support the cantilevered or may be configured with varied resilience to accommodate different sizes of the wafers.

It is important that the material or spring selected for the compression spring 218 or resilient member 229 has a force of compression (the force to which the material or spring yields when being compressed) such that it is responsive to the degree of the force exerted from the expanding wafer 12. Provided that the material for the spring 218 or resilient member 229 is properly selected, its compression should compensate for the increase in wafer size so that the wafer 12 is held in a precisely horizontal position during heat-up. That is, no sagging or bowing of the heated wafer will occur when a 300 mm wafer is supported by the edge handler 128 with the resilient member 136. As a result, no additional structures to support the wafer than the two edge handlers 126, 128 are required to prevent the wafer sagging during the pre-heat. Therefore, bowed wafers and breakage are avoided while the heating chamber structure is maintained without substantial change. The wafer handlers of known designs are not able to avoid the deleterious thermally induced force.

In addition to compensating for the wafer expansion, the compensation spring 218 or resilient member 229 also provides for a greater degree of stability of the wafer 12 on the edge handlers 126, 128. When the wafer 12 is expanding during the heat-up, the compression spring 218 or resilient member 229 is compressed. The reactive force developed in the compressed member 218, 229 is exactly proportional to the force exerted on it by the expanded wafer 12. This reactive force is applied back to the wafer 12, holding the wafer 12 clamped in a fixed position on the end effectors 136, 138 and laterally containing its narrow peripheral exclusion zone 50 within the pockets 168, 170.

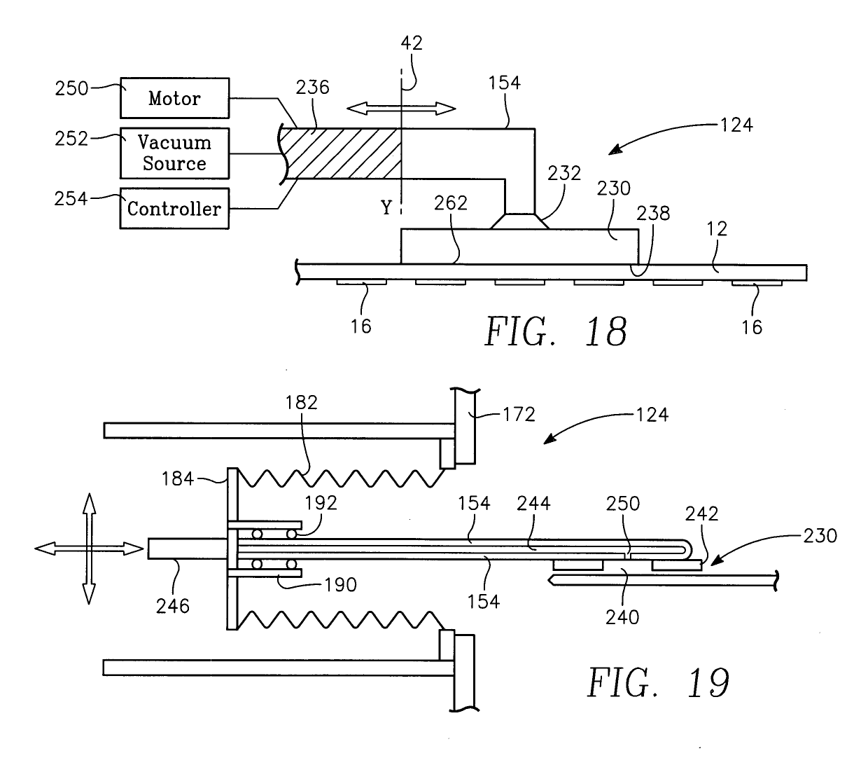

FIGS. 18 and 19 show respectively side overall and detailed views of the back handler 124. When activated, the back handler 124 pneumatically holds the wafer 12 from its featureless back side against the force of gravity to unload the wafer 12 to and from the edge ring of the heat chamber 10. Similarly to the edge handlers 126, 128, all parts of the back handler 124 are preferably made of quartz. The back handler 124 typically comprises a pneumatic cup 230, a mounting flange 232, the arm 154, and a conduit system 236 forming an extension of the arm 154. Coupled to the frame 230, the mounting flange is used to mount the frame of the pneumatic cup 230 to the arm 154. The mounting flange 232 may be an integral part of the pneumatic cup frame 230 or alternately may be fastened separately. The pneumatic cup 230 comprises a wafer holding area 238 that is used to hold the wafer 12 on the pneumatic cup 230 and to seal the sides of the cup 230. In one embodiment shown in FIG. 19, the holding area includes a vacuum area 240 surrounded by a sealing ridge 242 within which vacuum may be drawn to act on the wafer 12. The wafer holding surface 238 may be machined integrally within the frame of the pneumatic cup 230, but may alternately be a separate insert or made from a different suitable material.

In order for the back handler 124 to operate inside of the heating chamber 10, an interior bore 244 of the arm 184 is extended into the chamber 10 through a sealed aperture in the chamber wall 10 via the vacuum tight bellows 182, the operation of which was discussed in detail above. The O-rings 192 both support the arm 254 and seal it as it passes through an aperture in the bellows end plate 184 to thus maintain a precise horizontal position of the pneumatic cup 230. All mechanics of the operation of the back handler 124 are controlled from the outside of the chamber, through an arm stub 246 of the arm 124 in various manners as discussed for the edge handlers 126, 128.

The mechanical flexibility of the bellows 18 enables the back handler 124 to move laterally and vertically, as shown on FIG. 19, thus allowing for high manipulative flexibility in transferring the wafer 12. Alternatively, a robotic micromanipulator with a step motor 250 and a vacuum source 252, both controlled by a computerized controller 254, can be connected to the arm stub 246 to control, exactly position and fine tune the operation of the arm 124 positioned inside the heating chamber. While the arm stub 246 is shown as positioned outside of the heating chamber 10, it should be understood that alternative configurations may be possible.

In operation, the wafer 12 is held supported and clamped by the edge handlers 126, 128 during the transfer from the loading blade 102 to the position of pre-heat and during the pre-heat. Upon completion of the pre-heating, the wafer 12 is transferred to the edge ring 14. If the actuator 140, 142 of FIG. 15 is used, the transfer may be effected by de-energizing the electromagnet 210 so as to release the magnetic yoke 212, which is pulled back by the tension spring 228. If the handlers on opposed sides of the wafer 12 provide the same electrical signal to their respective electromagnets, the yokes 212 of both actuators 140, 142 are simultaneously released. The force of the pre-loaded tension spring 228 is strong enough to horizontally retract the end effectors 136, 138 faster than gravitational force pulls the wafer 12 in a downward direction. This allows the wafer 12 to be lowered to the underlying edge ring 14 without scratching. The profile of the sloping end of the end effectors 168, 170 is such that the wafer edge remains free of the end effector 168, 170 during downward transfer. For instance, if the effective force exerted on the edge handlers 126, 128 by the spring 218 is the same as the gravitational force, then the slop 168, 170 of the end effector 136, 138 needs to be greater than 45°.

Alternatively to dropping the wafer 12 from the end effectors 136, 138 onto the edge ring 14, the pneumatic cup 130 of the back handler 124 may be used to controllably lift the wafer 12 from the end effectors 136, 136, which are then withdrawn, and then lower the wafer 12 onto the edge ring 14.

Upon completion of the thermal processing, the wafer 12 is picked by the back handler 124 to be transferred back to the loading blade 102.

The conduit system 236 of FIG. 18 can be positioned to communicate with a drilled or otherwise formed vacuum passage 244 of FIG. 19 within the carrier arm 154 and may be connected to the motor 250, the vacuum source 252, and the controller 254 to provide for movement, vacuum or electrostatic chucking, and control over the operation of the back handler 124. It should be understood that while the foregoing description is only illustrative of one embodiment of the back handler 124, various alternatives and modifications can be devised by those skilled in the art without departing from the principles of this design. All these alternatives, modifications and variances are intended to be embraced in this description.

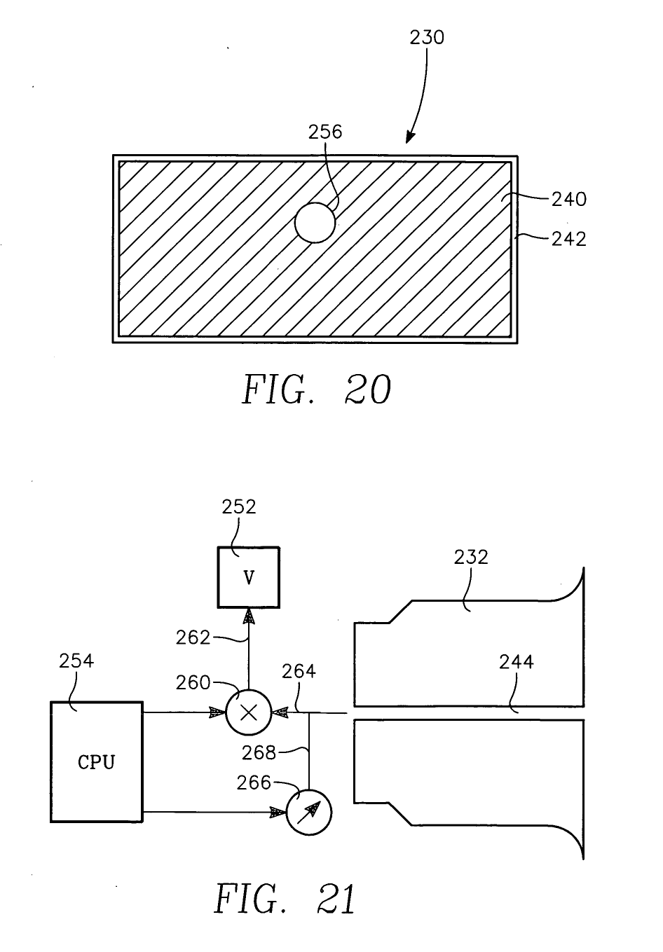

FIGS. 20 and 21 respectively show bottom plan and schematic section views of the pneumatic cup 230 and the mounting flange 232 of the back handler 124. A vacuum port 256 is formed in the pneumatic cup 230 to allow a vacuum to be pulled in the pneumatic recess 240 formed within the surrounding sealing wall 242, which contacts the back side of the wafer 12 to thereby hold it beneath the pneumatic cup 230.

The vacuum source 252, for example a vacuum pump positioned outside of the heat chamber, is connected to the passageway 244 which is formed in the mounting flange 230 connected to the vacuum port 250 in the pneumatic cup 230. The vacuum pump 252 may be a diaphragm pump, centrifugal pump, ejector pump or other suitable source of vacuum. A valve 260 isolates the vacuum pump 252 from the vacuum passage 244. The valve 260 is connected to the vacuum pump 252 with tubing 262 and to the mounting flange 232 with tubing 264. A pressure switch 266 may be in communication with the vacuum passage via the tubing 268. The pressure switch 266 senses the vacuum level and may trigger a bit when the vacuum level in the vacuum passage 244 reaches a preset level or may have a readable output proportional to the vacuum level in the vacuum passage 244. The pressure switch 266 and the valve 260 may be connected to the controller 254 to control the operation of the back handler 124.

The actuator 152 of the back handler 124 may be implemented in a number of ways including those of FIGS. 14 and 15.

The use of vacuum chucking for holding of the back of the wafer 12 can be implemented if the chamber pressure is near atmospheric, for example, above 1 Torr. However, if the thermal processing is performed in a chamber under low pressure, the back handler 124 may be implemented with an electrostatic chuck where the chuck electrode may be embedded in the holding surface 238. Under proper electrical biasing, the electrostatic chuck tightly holds the wafer 12. A ceramic electrostatic chuck may be required for high-temperature operation while a polymeric chuck will suffice for low-temperature operation.

In operation, when thermal processing is completed, the actuator 152 of the back handler 124, is extended towards the center of the heater chamber 10 to position the pneumatic cup 230 over the wafer 12 which overlies the edge ring 14 in inverted orientation. When the back handler 124 is activated, i.e., the vacuum pump 252 pumps the vacuum recess 240, and the valve 260 is open, negative pressure is applied to the featureless back side of the wafer 12 through the vacuum passage 244 via the vacuum port 250 such that the hold surface 238 can support the wafer 12 against the force of gravity. To unload the wafer 12 from the edge ring 14, the pneumatic cup 230 is lowered and vacuum chucks the back surface of the wafer 12 and lifts the wafer 12. The loading blade 102 is inserted beneath the raised wafer 12 and the pneumatic cup 230 is lowered to place the wafer 12 on the blade 102. The vacuum on the back handler 14 is then inactivated, i.e., the valve 260 is closed, and the pneumatic cup 230 and the back handler 124 are easily detached from the wafer 12 by movement in the vertical direction. The loading blade 102 then removes the wafer 12 from the chamber 10. In addition to the unloading function, the back handler 124 can be used for holding the wafer 12 in conjunction with the edge handlers 126, 128, thus allowing for even greater stability of the wafer 12 during the loading process. Alternatively, the back handler 124 can be used alone for both the loading and unloading wafer operations, in which case the back handler 114, without the edge handlers 126, 128 would transfer the wafer 12 to overlie the edge ring 106 under the heating lamps and would withdraw from the center of the chamber to return for the unloading of the wafer 12 after the thermal processing is completed.

The edge handlers 126, 128 and the back handler 128 may be connected to and controlled by the one controller 254. The controller 254 may be a microprocessor or digital signal processor, or any other type of computer that is suitable to operate and control the edge handlers 126, 128 and the back handler 128 such that the wafer 12 may be selectively picked or placed for thermal processing described above. The pressure switch 266 in communication with the vacuum passage 244 and wafer sensors positioned to detect the presence of a wafer on the wafer handlers 124, 126, 128 respectively, may be connected to the controller 254 for a better control of the wafer handling apparatus 100.

The apparatus of the invention for transferring wafer in an inverted orientation offers several advantages. First, the two-point edge contact with 1.5 mm or less intrusion augmented by the one-point top contact increases the active wafer surface, and thus the number of devices that can be manufactured on the wafer surface. Other advantages of the present invention include: (1) the elimination of the breakage or scratching of the wafers surface by the fixed positioning of the wafer and adaptive correction for thermal expansion that prevents warping and lateral movement of the wafer; (2) the increased efficiency in transferring the wafer within the heating chamber by providing a setup that allows to eliminate the vertical movement of the loading blade and minimizes interference from the wafer handlers with the thermal process, thus significantly increasing the throughput of the system; (3) the improved reliability of the wafer support system from the fixtures constructed out of material that is able to withstand high wafer temperatures and ramp downs in the RTP reactors; and (4) the maximized efficiency of the thermal processing from providing a controllable location for the wafer in the heating chamber during the pre-heat stage of the process.

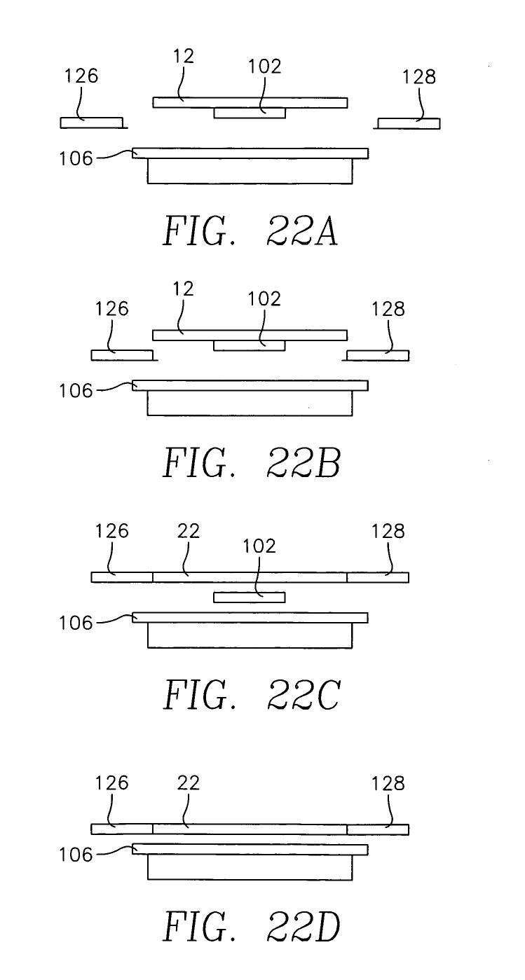

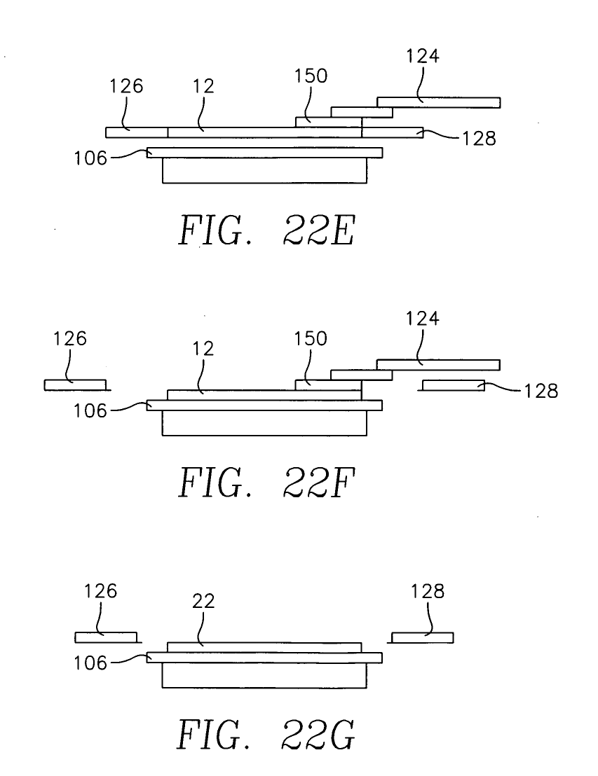

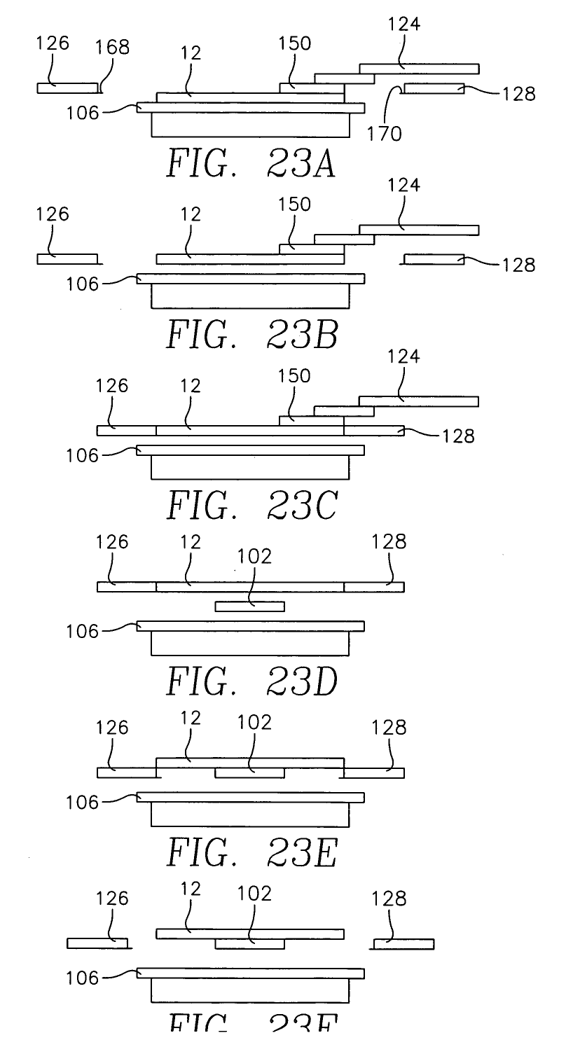

FIGS. 22A-22G and 23A-23F illustrate the method of handling and transferring the wafer 12 in the environment of the heating chamber in accordance with an embodiment of the present invention.

FIGS. 22A through 22G shows the sequence of events of loading the wafer 12 from the loading blade 102 onto the edge ring 106. The process begins at FIG. 22A with the loading blade 102 bringing the wafer 12 in an inverted orientation into the heating chamber for thermal processing. The edges of the wafer 12 are not touched inside of the 1.5 mm wafer edge exclusion zone. At FIG. 22B, the edge handlers 126 and 128 of the wafer transfer mechanism move from a remote, or “home”, position close to the wafer edges, on both sides of the wafer 12, to assume a position underneath the wafer. At FIG. 22C, the edge handlers 126 and 128 move up and lift up about 10 mm to raise the wafer 12 from the blade 102. As the wafer 12 is positioned in inverted orientation on the sloping surfaces 160, 162 of the pockets 168, 170 of the edge handlers 126 and 128, the edges of the wafer 12 are minimally touched by the sloping surfaces 160,162 inside the 1.5 mm exclusion zone due to their sloped shape. The pockets 168, 170 firmly hold the inverted wafer 12 in a horizontal position and prevent the wafer 12 from lateral movement.

At FIG. 13D, the loading blade 102 is retracted from underneath the raised wafer 12 and the wafer 12, clamped from both sides in the pockets 168, 170 at the edges within 1.5 mm of the exclusion zone, is lowered by and the edge handlers 126 and 128 down 10 mm to a pre-heat position above the edge ring 106, and pre-heat begins. While the edge handler 126 is controlling the exact fixed position of the wafer 12, the spring-loaded edge handler 128 compensates for thermal expansion of the wafer 12 under the high temperatures of pre-heat. At FIG. 22E, at the completion of pre-heat, the back handler is moved towards the wafer 12 and then lowered so that its pneumatic cup 150 faces the back of the wafer 12. After the pneumatic vacuum is applied so that the pneumatic up 150 holds the wafer 12, the back handler 124 is slightly raised or the edge handlers are lowered to allow the two edge handlers 126, 128 to withdraw. At FIG. 22F, the back handler 124 lowers the wafer 12 onto the edge ring 106. The pneumatic vacuum is released and the back handler 124 is raised and withdrawn. Alternatively, if required, the edge ring 106 can be lifted up to 5 mm by magnetic levitation to meet the wafer 12. At FIG. 22, the wafer 12 rests on the edge ring 106, which can then begin to rotate for the main thermal processing.

In a variant of the loading procedure, the back handler 124 is not used. Instead, after pre-heat, the edge handlers 126, 128 lower the wafer 12 to the edge ring 106 and then drop it onto the edge ring 106 by retracting away from the edge of the wafer 12.

FIGS. 23A through 23F show the sequence of events of unloading the wafer 12 from the edge ring 106 onto the loading blade 102. At FIG. 23A, the edge ring 106 with the inverted wafer 12 is lifted by magnetic levitation approximately 5 mm. The back handler 124 moves over the wafer 12 to a position over the wafer 12 and then lowers to the backside of the wafer 12. Alternatively, the back handler 124 can lower to the backside of the wafer 12 without lifting the edge ring 10. At FIG. 23B, the controller 254 turns on the vacuum source 254, which activates vacuum in the pneumatic cup 230. The controller 254 then monitors the vacuum valve 260 until a vacuum pressure setpoint has been reached, at which time the controller 254 would indicate that the wafer 12 has been gripped. The back handler 124, holding the wafer 12 by chucking, lifts it off the edge ring 106 up about 10 mm In the heating chambers where the thermal processing is performed at atmospheric pressure, the chamber opens at this step, and the blade 102 moves to a position underneath of the wafer 12.

At FIG. 23C, to release the wafer 12, the controller 230 turns off the vacuum source 214 or closes the valve 216, allowing the vacuum passage 198 and, as a result, the volume in communication with the pneumatic cup 230, to vent back to atmospheric pressure or other high pressure. The wafer 12 is then released onto the blade 102, which is retracted out of the heating chamber along with the wafer 12. In a typical RTP heating chambers, however, at FIG. 23C, the wafer 12 is first released from the back handler 124 to the edge handlers 126, 128 to allow the chamber pump down before being opened. The edge handlers 126, 128 move laterally toward the wafer 12 and up to the level of the wafer 12 to support it on the edge handlers 126, 128. The edge handlers 126, 128 clamp the wafer 12 within the pockets 168, 170, while the vacuum source 252 is turned off, and the vacuum hold of the back handler 124 is deactivated. The back handler 124 moves up, and is retracted from the chamber. At FIG. 23D, as the chamber 10 is pumped for transfer out, the edge handlers 126 and 128 with the supported wafer 12 move to the loading position and the loading blade 102 moves underneath the wafer 12. At FIG. 23E, the edge handlers 126, 128 move down then apart to transfer the wafer 12 on the blade 102. The blade 102 moves the processed wafer 12 out of the heating chamber 10 in FIG. 23F.

While the present invention has been described in connection with specific embodiments, one of ordinary skill in the art after having reviewed the present disclosure. will recognize that various substitutions, modifications and combinations of the embodiments may be made after having reviewed the present disclosure. The specific embodiments described above are illustrative only. Various adaptations and modifications may be made without departing from the scope of the invention. For example, various types of materials and dimensions may be used in accordance with the present invention. Thus, the spirit and scope of the appended claims should not be limited to the foregoing description

1. An apparatus for handling a wafer during thermal processing in a heating chamber with a radiant heat source, comprising:
a loading blade for delivering in a wafer transfer direction the wafer into the heating chamber to be thermally processed on a front side to form features therein with the wafer front side facing away from the heat source;
an edge ring for holding the wafer at its periphery during thermal processing; and;
a wafer handling mechanism for transferring the wafer between the loading blade and the edge ring with a wafer back side, opposite the front side, facing the heat source;
wherein the wafer handling mechanism independently gravitationally supports the wafer at at least two points of contact at a peripheral portions of the wafer front side.

2. The apparatus of claim 2, wherein the wafer handling mechanism comprises at least two co-planar edge handlers for supporting the wafer at two opposite wafer edges.

3. The apparatus of claim 2, wherein each of the at least two edge handlers supports the wafer within a distance that is less than the wafer edge exclusion zone.

4. The apparatus of claim 5, wherein the wafer is supported at the edges within less than 1.5 mm contact to the surface around the edges.

5. The apparatus of claim 4, wherein the at least two edge handlers comprise at least one restraining edge handler configured to support the wafer in a fixed position to restrain the wafer from lateral movement in a direction to perpendicular to the direction of transfer.

6. The apparatus of claim 5, wherein the at least two edge handlers further comprise at least one compensating edge handler configured to expand to adapt to the thermal expansion of the wafer.

7. The apparatus of claim 2, wherein the wafer handling mechanism further comprises at least one back handler for supporting the wafer from its back side, and wherein the at least one back handler is configured to gravitationally support the wafer independently from the at least two edge handlers in a position perpendicular to the wafer transfer direction.

8. The apparatus of claim 7, wherein the rear handler is configured to support the wafer by vacuum chucking.

9. The apparatus of claim 7, wherein the rear handler is configured to support the wafer by electromagnetic force.

10. The apparatus of claim 6, wherein the at least one restraining edge handler and at least one compensating edge handler are configured to support the wafer during pre-heat at about 650° C. and above.

11. The apparatus of claim 8, wherein the at least two edge handlers and the rear handler are made of a material that is not a metal and is selected from a group consisting of glass and quartz.

12. The apparatus of claim 7, further comprising respective drives connected to the at least two edge handlers and the at least one rear handler, and a controller connected to the drives, for independently controlling each of the at least two edge handlers and the at least one rear handler.

13. The apparatus of claim 12, further comprising respective arms connected between respective drives and handlers, wherein the arms are independently movably connected to each of the at least two edge handlers and the at least one rear handler.

14. The apparatus of claim 13, further comprising a vacuum source, wherein the arm and the at least one rear handler have a vacuum passage adapted to be connected to vacuum source and wherein the controller is configured to control the vacuum source

15. The apparatus of claim 16, wherein the at least two edge handlers and the at least one rear handler penetrate the heating chamber's walls and wherein a penetration is vacuum tight sealed and is configured to adapt for independent movement of each of the at least two edge handlers and at least one rear handler inside the heating chamber from outside of the heating chamber.

16. A wafer handling apparatus for transferring a wafer within a heat reactor including a heat source, comprising:
a first end effector supporting the wafer in a fixed position at a first point of contact and configured to restrain the wafer from lateral movement in a horizontal direction;
a second end effector supporting the wafer at a second point of contact, co-planar with the first point of contact, and configured to compensate for the thermal horizontal expansion of the wafer; and
a back effector supporting the wafer at a third point of contact independently from the first and second end effectors;
wherein the wafer is gravitationally supported in a horizontal position with a back generally featureless side facing the heat source; and wherein at the first and second points of contact, the wafer is supported at the edges within less than 1.5 mm of contact, and at the third point of contact the wafer is supported from a back side, opposite the front side, by chucking,

17. The apparatus of claim 16, further comprising respective drives connected to the first end effector and the second end effector, a vacuum source connected to the back effector, and a controller, wherein the drives and the vacuum source are connected to the controller, and wherein the controller is configured to independently movably control each of the first end effector, second end effector, and back effector.

18. The apparatus of claim 17 wherein the first end effector, the second end effector, and the back effector penetrate inside the heating chamber at a vacuum tight sealed aperture and are manipulated by the drives from an exterior of the heating chamber by an arm.

19. The apparatus of claim 18, wherein the material of the first end effector, second end effector, back effector, and arm is selected from a group consisting of glass and quartz.

20. A method of handling a wafer during thermal processing in a heating chamber with a radiant heat source, comprising the steps of:
holding the wafer on a loading blade in an up position with a front side to form features therein facing away from the heat source;
positioning at least two edge handlers in co-planar positions under the wafer to place the wafer thereon, each of the at least two handlers being independently moveable from the outside of the heating chamber;
raising the at least two edge handlers to an up position to support the wafer thereon at two opposite edges of the wafer within a distance that is less than the wafer edge exclusion zone;
retracting the loading blade from the heating chamber;
lowering the at least two edge handlers to a down position for the wafer pre-heat, with the wafer back side, opposite the front side, facing the heat source; and
retracting the at least two edge handlers after the pre-heat to place the wafer on the edge ring for thermal processing.

21. The method of claim 20, wherein the step of rising comprises supporting the wafer within less than 1.5 mm contact to the surface around the edges.

22. The method of claim 20,wherein the step of lowering comprises supporting the wafer in a fixed position to restrain it from lateral movement and adapting at least one of the at least two edge handlers to compensate for thermal expansion of the wafer.

23. The method of claim 20, further comprising:
positioning at least one back handler over the wafer being held on the edge ring, the back handler being moveable from the outside of the heating chamber;
lowering the at least one back handler to the edge ring to grip the wafer at the back by chucking;
raising the back handler to the up position to release the wafer from chucking on the at least two edge handlers;
positioning the at least two edge handlers under two opposite edges of the wafer to support the wafer with the wafer featureless back facing the heat source;
retracting the at least one back handler;
extending the loading blade;
raising at least two edge handlers to place the wafer on the loading blade; and
retracting the loading blade to remove the wafer from the heating chamber.

24. The method of claim 23, wherein the at least two edge handlers and at least one back handler are independently movably connected to respective arms, and wherein the at least two edge handlers and at least one back handler are moved by moving the arms from outside of the heating chamber.

25. A method of loading and unloading a wafer onto and off of a heating chamber for thermal processing, comprising:
delivering the wafer on a loading blade with a front side to form features therein facing downwardly;
moving two effectors under the wafer to support the wafer at opposing edges thereof within less than 1.5 mm contact with each effector;
gripping the wafer by the two effectors to restrain the wafer from lateral movement;
retracting the loading blade;
moving the two effectors to position the wafer for pre-heat;
pre-heating the wafer supported by the effectors;
then loading the pre-heated wafer onto an edge ring; and
retracting the two effectors.

26. The method of claim 25, further comprising:
lowering a back effector to grip the wafer at a back side, opposite to the front side, by chucking;
unloading the wafer from the edge ring;
moving the back effector to position the wafer for being placed on the two end effectors;
moving the two end effectors to support the wafer at opposing edges thereof;
retracting the back effector;
extending the loading blade to load the wafer on the loading blade; and
retracting the loading blade from the heating chamber.

27. The method of claim 26, wherein the wafer is supported within less than 1.5 mm contact thereof with each end effector.

28. The method of claim 26, wherein the step of loading the wafer on the edge ring comprises raising the edge ring to position the wafer on the edge ring.

29. The method of claim 26, wherein the step of unloading the wafer from the edge ring comprises raising the edge ring to position the wafer for being placed on the two end effectors.
